(19) United States
(12) Patent Application Publication
(10) Pub. No.: US 2005/0192364 A1
(43) Pub. Date: Sep. 1, 2005

(54) Polyhedral oligomeric silsesquioxanes and metallized polyhedral oligomeric silsesquioxanes as coatings, composites and additives

(76) Inventors: Joseph D. Lichtenhan, Petal, MS (US); Xuan Fu, Hattiesburg, MS (US); Steven R. LeClair, Gaithersburg, MD (US)

Correspondence Address: PILLSBURY WINTHROP SHAW PITTMAN LLP, P.O. BOX 10500, MCLEAN, VA, 22102, US

(21) Appl. No.: 11/015,185

(22) Filed: Dec. 17, 2004

Related U.S. Application Data
(60) Provisional application No. 60/531,458, filed on Dec. 18, 2003.

(51) Int. Cl. C08J 9/00; C07F 7/22; C08F 8/00; C08L 83/00; H01L 21/4763

(52) U.S. Cl. 521/50; 556/90; 525/101

(57) ABSTRACT

A method of using metallized and nonmetallized nanoscopic silicon containing agents for physical property control, radiation absorption, and in situ formation of nanoscopic glass layers on material surfaces. Because of their tailorable compatibility with polymers, metals, composites, ceramics, glasses and biological materials, nanoscopic silicon containing agents can be readily and selectively incorporated into materials at the nanometer level by direct mixing processes. Properties improved include gas and liquid barrier, stain resistance, resistance to environmental degradation, radiation absorption, adhesion, printability, time dependent mechanical and thermal properties such as heat distortion, creep, compression set, shrinkage, modulus, hardness and abrasion resistance, electrical and thermal conductivity, and fire resistance. The materials are useful in a number of applications, including beverage and food packaging, space-survivable materials, microelectronic packaging, and radiation absorptive paints and coatings.

### CROSS-REFERENCE TO RELATED APPLICATIONS

This application claims the benefit of U.S. Provisional Application Ser. No. 60/531,458 filed on Dec. 18, 2003.

### FIELD OF THE INVENTION

This invention relates generally to methods for enhancing the properties of thermoplastic and thermoset polymers of man-made or natural origins and their compositions. More particularly, it relates to the incorporation of nanostructured chemicals into such polymers for radiation absorption, in situ glassification, gas and moisture barriers, and modification of surface and bulk properties.

The applications for such materials include use in coatings and molded articles that benefit from radiation resistance, stain resistance, printability, scratch resistance, low permeability, low surface roughness, and unique electronic and optical properties.

### BACKGROUND OF THE INVENTION

The invention is related to use of polyhedral oligomeric silsesquioxane (POSS), silsesquioxane, polyhedral oligomeric silicate, silicates, silicones or metallized-polyhedral oligomeric silsesquioxane, silsesquioxane, polyhedral oligomeric silicate, silicates, and silicones as alloyable agents with polymeric materials. Polyhedral oligomeric silsesquioxane, silsesquioxane, polyhedral oligomeric silicate, silicates, silicones and metallized-polyhedral oligomeric silsesquioxane, silsesquioxane, polyhedral oligomeric silicate, silicates, silicones are here after referred to as Silicon Containing Agents.

Silicon Containing Agents have previously been utilized to complex metal atom(s) as reported by Abbenhuis et. al in U.S. Pat. No. 6,441,210. As discussed by Lichtenhan et. al in U.S. Pat. No. 6,716,919 and WO 01/72885 A1, such Silicon Containing Agents are useful for dispersion and alloying of silicon and metal atoms with polymer chains uniformly at the nanoscopic level. As discussed by Lichtenhan et al. in U.S. Pat. No. 6,767,930, Silicon Containing Agents can be converted in the presence of atomic oxygen to form a glass like silica layer which is useful in the protection of spacecraft from atomic oxygen.

It is now surprisingly discovered that such Silicon Containing Agents are also useful for the formation of gas and liquid barriers and as additives for absorbing radiation. In such capacity, the Silicon Containing Agents are themselves effective when alloyed into a polymer but may also be preferably utilized for the in situ formation of nanoscopically thin glass barriers. This process can be carried out in a facile manner through exposure of polymers containing the Silicon Containing Agents to oxygen plasma, ozone, or an oxidizing flame. The resulting nanoscopically thin glass layers provide exceptional barrier and radiation absorption properties. Upon exposure to such oxidants, the Silicon Containing Agents render surface glass layers comprised of silica and metallized silica. Advantages of the method and nanoscopically thin glass layer include: nondetectable by the human eye, toughness and flexibility, suitability for storage on rolls and thin film packaging, impermeability to moisture and gas, direct printability, stain resistance, scratch resistance, lower cost and lighter weight than glass, excellent adhesion between polymer and glass due to elimination of discreet compositional bondlines and replacement of them by compositionally graded material interfaces. Finally, nanoscopically thin glass layers containing metals absorb photon and particle radiation that could otherwise damage polymer surfaces and substrates. In this same capacity, nanoscopically thin glass layers containing mixtures of metals may also be utilized as phosphores and luminescent materials, or in combination with existing phosphorescent and luminescent materials. Prior art with nonmetalized POSS such as U.S. Pat. No. 6,517,958 has shown it to enhance the brightness of semiconducting and luminescent polymers but failed to recognize the potential for luminescent contributions of metallized POSS.

As has been discussed in U.S. Pat. Nos. 6,127,557 and 5,750,741, prior art in metallized-polyhedral oligomeric silsesquioxane, silsesquioxane, polyhedral oligomeric silicate, silicates, and silicones has focused on their utility in catalysis for epoxidation of olefins and the addition polymerization of olefins. However, metallized silicon agents had not been recognized as useful as polymer stabilizers nor as radiation absorbers. Nor had the metallized POSS been described as useful as a catalyst in condensation polymerizations. They have been found particularly useful in the condensation polymerization of polyurethanes and epoxides and bismaleimide and silicone materials.

The use of metals and organic metal complexes as polymer stabilizers are well known items of commerce. However, such metals-based stabilizer additives are not available in a form that allows them to be incorporated into a polymer and to serve as a glass forming precursor.

The use of metals and metal particles such as boron and gadolinium is also known to be of use in fast neutron tumor therapy, see U.S. Pat. Nos. 5,630,786 and 6,248,916. A shortcoming of this prior art is that neutron trapping agents such as carboranes lack high enough proton concentrations to effectively slow enough fast neutrons to a capturable energy level. This causes patients to be subjected to longer radiation exposures and higher dosages of the neutron capturing particle. This deficiency can be mitigated by the incorporation of metals such as boron, samurium, and gadolinium into nanoscopic POSS systems as the protons on the organic arms of the cage thermalize fast neutrons.

The incorporation of metal particles into a polymeric binder and its application as a conformal coating for the absorption of X-ray, electron radiation discussed in U.S. Pat. No. 6,583,432. However, this approach is deficient in that it does not afford an optically transparent coating, it requires careful preparation and application procedures to avoid becoming electrically conductive, and it does not afford protection against thermal and fast neutron radiation. The sensitivity of commercial electronic components to damage by thermal neutrons is well known as is the absence of a low cost and neutron effective polymeric shielding material. Therefore, the use of metallized Silicon Containing Agents for the specific absorption of neutron radiation in a conformal coating or potting agent with or without a passivating glass layer is a needed improvement over prior art coatings.

A number of prior art methods are known to produce glass coatings and metallized glass coatings on polymers. Such methods include elevated temperature sintering, sputtering, vapor deposition, sol-gel, and coating process which all require additional manufacturing steps and are not amenable to high speed molding and extrusion processing. These prior art methods also suffer from poor interfacial bonding between the glass and polymer layers. The prior art is also deficient in its ability to incorporate metal and nonmetal atoms into a well defined nanoscopic structure within a single glass layer. Finally, the prior art is not able to produce nanoscopically thin glass surfaces and consequently the methods are not amenable to the high speed manufacture of flexible film packaging and especially bottling and film manufacture.

The Silicon Containing Agents of the present invention are best exemplified by those based on low cost silicones such as silsesquioxanes, polyhedral oligomeric silsesquioxanes (POSS), and polyhedral oligomeric silicates. FIG. 1 illustrates some representative examples of Silicon Containing Agents containing siloxane, silsesquioxane, and silicate examples. The R groups in such structures can range from H to alkane, alkene, alkyne, aromatic and substituted organic systems including ethers, acids, amines, thiols, phosphates, and halogenated R groups. The structures and compositions are also intended to include metallized derivatives where metals ranging from high to low Z can be incorporated into the structures as shown in FIG. 2.

The Silicon Containing Agents all share a common hybrid (i.e. organic-inorganic) composition in which the internal framework is primarily comprised of inorganic silicon-oxygen bonds. Upon mild and further oxidation these systems readily form silica glasses. The exterior of a nanostructure is covered by both reactive and nonreactive organic functionalities (R), which ensure compatibility and tailorability of the nanostructure with organic polymers. These and other properties of nanostructured chemicals are discussed in detail in U.S. Pat. No. 5,412,053 and U.S. Pat. No. 5,484,867 to Lichtenhan, both of which are incorporated herein by reference. These nanostructured chemicals are of low density, and can range in diameter from 0.5 nm to 5.0 nm and can be utilized in combination with micron sized metal fillers.

### SUMMARY OF THE INVENTION

The present invention describes a new series of polymer additives and their utility in the absorption of radiation, gas and liquid barrier formation, catalysis of condensation polymerization, and in situ formation of nanoscopic glass layers. The metallized POSS are wholly useful by themselves or in combination with polymers, or metals, or composites or in combination with macroscopic reinforcements such as fiber, clay, glass, metal, mineral, and other particulate fillers.

The metallized POSS are particularly useful as polymeric compositions with special radiation absorption, emissive, and refractive characteristics, and in packaging for enhanced printability, stain resistance, gas and liquid barrier properties. The metallized POSS are also useful in catalyzing the condensation polymerization of reactive monomers. Finally, the metallized and nonmetallized POSS are useful for in situ formation of nanoscopically thin glass layers.

The preferred compositions presented herein contain three primary material combinations: (1) Silicon Containing Agents including nanostructured chemicals, nanostructured oligomers, or nanostructured polymers from the chemical classes of silicones, polyhedral oligomeric silsesquioxanes (POSS), polysilsesquioxanes, polyhedral oligomeric silicates, polysilicates, polyoxometallates, carboranes, boranes; (2) metal atoms including alkali, alkaline earth, transition metals, lanthanide and actinide metals; and (3) manmade polymer systems such as polystyrene, polyamides, polyolefins, polyurethanes, polyesters, polycarbonates, polyethers, epoxy, cyanate esters, maleimides, phenolics, polyimides, fluoropolymers, rubber, and natural polymers including cellulosics, sugars, starches, proteins, chitins, and all semicrystalline, crystalline, glassy, elastomeric polymers and copolymers thereof.

The preferred method of incorporating the Silicon Containing Agents into thermoplastics is accomplished via melt mixing into the molten polymers. The incorporation of the Silicon Containing Agents into thermosets can be accomplished through melt blending, milling or solvent assisted methods or by dissolving into compatibilizing monomers. All types and techniques of blending, including melt blending, dry blending, solution blending, reactive and nonreactive blending are effective.

In addition, the selective incorporation and maximum loading levels of a Silicon Containing Agent into a specific polymer can be accomplished though use of a Silicon Containing Agent with a chemical potential (miscibility) compatible with the chemical potential of the region within the polymer in which it is to be alloyed. Because of their chemical nature, Silicon Containing Agents can be tailored to show compatibility or incompatibility with selected sequences and segments within polymer chains and coils. Their physical size in combination with their tailorable compatibility enables Silicon Containing Agents based on nanostructured chemicals to be selectively incorporated into polymers and to control the dynamics of coils, blocks, domains, and segments, and subsequently favorably impact a multitude of physical properties. A picture illustrating attainment of a 1-3 nm level of dispersion is shown in FIG. 3.

The process of forming in situ glass glazings on articles molded from or coated by polymers alloyed with Silicon Containing Agents is carried out by exposure of the articles to oxygen plasma, ozone, or other highly oxidizing mediums. These chemical oxidation methods are desirable as they are current industrial processes and they do not necessarily result in heating of the polymer surface. There are no topological constraints on the molded articles. Both thin films and thick parts derived from the alloyed polymers can be processed to contain nanometer thick surface glass layers. The most efficient and thereby preferred oxidation method is oxygen plasma. However for alloys where the R on the Silicon Containing Agents is H, methyl or vinyl, they can be converted to glass upon exposure to ozone, peroxide, or even hot steam. A reliable alternate to the above methods is the use of an oxidizing flame or laser operating in an oxidizing atmosphere. The choice of method is dependent upon the chemical agent, polymer alloy system, loading level of the silicon containing chemical agent, surface segregation of agent, the thickness of the silica surface desired, and manufacturing considerations. A schematic view of the alloyed and in situ glassified materials is shown in FIG. 4.

Upon exposure of the surface to the oxidation source, a nanoscopically thin layer of glass from 1-500 nm will result. If the Silicon Containing Agent contained a metal, then the metal will also be incorporated into the glass layer as shown in FIG. 5. Advantages derived from the formation of a nanoscopic glass surface layer include a smoother surface as shown in FIG. 6, barrier properties for gases and liquids, improved oxidative stability, flammability reduction, improved electrical properties, improved printability, improved stain and scratch resistance, and improved radiation resistance.

### BRIEF DESCRIPTION OF THE DRAWINGS

FIG. 1 shows representative structural examples of nonmetallized Silicon Containing Agents.

FIG. 2 shows representative structural examples of metallized Silicon Containing Agents.

FIG. 3 illustrates the ability to uniformly disperse nanostructured silicon agents at the 1-3 nm level at the surface and the bulk of a polymer.

FIG. 4 illustrates the conceptual comparison of an alloyed and nanoscopically surface glassified material.

FIG. 5 illustrates the chemical process of oxidative conversion of the silicon agents into a fused nanoscopically thin glass layer.

FIG. 6 illustrates the roughness of an alloyed surface and an in situ glassified surface.

FIG. 7 illustrates the ability to conformally coat an integrated circuit.

FIG. 8 illustrates the ability to attenuate neutron radiation.

FIG. 9 illustrates the effective shielding level for natural abundance Gd POSS loaded at 50% in a conformal coating.

FIG. 10 illustrates the effective shielding level for 157 isotopically enriched Gd POSS loaded at 50% in a conformal coating.

FIG. 11 illustrates the ability to form a nanoscopically thin barrier layers inside and outside a molded plastic article.

FIG. 12 illustrates the UV absorption ranges for metallized POSS.

### DEFINITION OF FORMULA REPRESENTATIONS FOR NANOSTRUCTURES

For the purposes of understanding this invention's chemical compositions, the following definition for formula representations of Silicon Containing Agents and in particular Polyhedral Oligomeric Silsesquioxane (POSS) and Polyhedral Oligomeric Silicate (POS) nanostructures is made.

Polysilsesquioxanes are materials represented by the formula [RsiO_{1.5}]_{∞} where ∞ represents molar degree of polymerization and R=represents organic substituent (H, siloxy, cyclic or linear aliphatic or aromatic groups that may additionally contain reactive functionalities such as alcohols, thiols, esters, amines, aldehydes, acids, ketones, esters, olefins, ethers or which may contain halogens). Polysilsesquioxanes may be either homoleptic or heteroleptic. Homoleptic systems contain only one type of R group while heteroleptic systems contain more than one type of R group.

A subset of Silicon Containing Agents are classified as POSS and POS nanostructure compositions are represented by the formula:
[(RsiO_{1.5})ₙ]_{Σ#} for homoleptic compositions
[(RsiO_{1.5})ₙ(R′SiO_{1.5})ₘ]_{Σ#} for heteroleptic compositions (where R≠R′)
[(RsiO_{1.5})ₙ(RsiO_{1.0})ₘ(M)ⱼ]_{Σ#} for heterofunctionalized heteroleptic compositions
[(RsiO_{1.5})ₙ(RXSiO_{1.0})ₘ]_{93 #} for functionalized heteroleptic compositions (where R groups can be equivalent or inequivalent)

In all of the above R is the same as defined above and X includes but is not limited to OH, Cl, Br, I, alkoxide (OR), acetate (OOCR), peroxide (OOR), amine (NR₂) isocyanate (NCO), and R. The symbols m, n and j refer to the stoichiometry of the composition. The symbol Σ indicates that the composition forms a nanostructure and the symbol # refers to the number of silicon atoms contained within the nanostructure. The value for # is usually the sum of m+n, where n ranges typically from 1 to 24 and m ranges typically from 1 to 12. It should be noted that Σ# is not to be confused as a multiplier for determining stoichiometry, as it merely describes the overall nanostructural characteristics of the system (aka cage size). The symbol M refers to metallic elements within the composition that include high and low Z metals and in particular Al, B, Ga, Gd, Ce, W, Ni, Er, Y, Zn, Mn, Os, Ir, Ta, Cd, Cu, Ag, V, As, Tb, In, Ba, Ti, Sm, Sr, Pb, Lu, Cs, Tl, Te.

### DETAILED DESCRIPTION OF THE INVENTION

The present invention teaches the use of Silicon Containing Agents as alloying agents for the absorption of radiation, formation of gas and liquid barrier properties, for the catalysis of condensation polymers, for the control of refractive index, for control of emissive properties, laser marking, in situ formation of glass layers in polymeric materials and for the reinforcement of polymer coils, domains, chains, and segments at the molecular level.

The keys that enable Silicon Containing Agents such as nanostructured chemicals to function in this capacity include: (1) their unique size with respect to polymer chain dimensions, (2) their ability to be compatibilized and uniformly dispersed at the nanoscopic level with polymer systems to overcome repulsive forces that promote incompatibility and expulsion of the nanoreinforcing agent by the polymer chains, (3) their hybrid composition and its ability glassify upon exposure to selective oxidants, and (4) the ability to chemically incorporate metals into the Silicon Containing Agents and into the corresponding glass rendered therefrom. Therefore, the factors to effect selection of a Silicon Containing Agent for radiation absorption include the specific wavelength and type of radiation, the loading level of the Silicon Containing Agent, and the optical, electronic, and physical properties of the polymers. The factors to effect selection of a Silicon Containing Agent for emissive and refractive index properties include the specific wavelength desired, the sensitivity desired, the loading level of the Silicon Containing Agent, and the optical, electronic, and physical properties of the polymers. The factors to effect selection of a Silicon Containing Agent for catalysis of condensation polymers include the type of polymerization, the rate of polymerization desired, and the type of metal necessary. The factors to effect selection of a Silicon Containing Agent for permeability control and glassification include the nanosizes of nanostructured chemicals, distributions of nanosizes, and compatibilities and disparities between the nanostructured chemical and the polymer system, the loading level of the Silicon Containing Agent, the thickness of the silica layer desired, and the optical, electronic, and physical properties of the polymer.

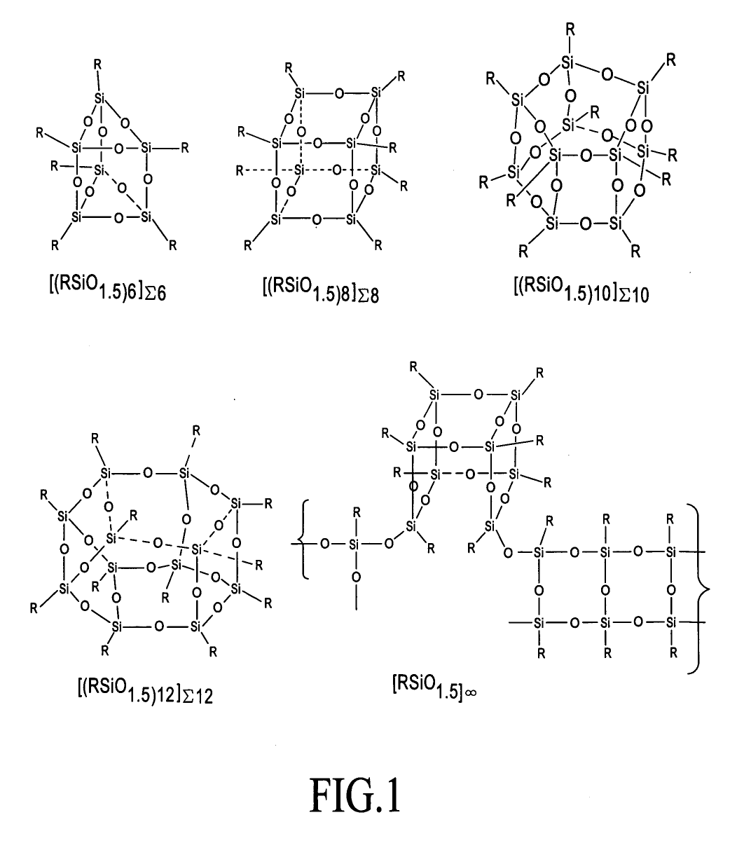

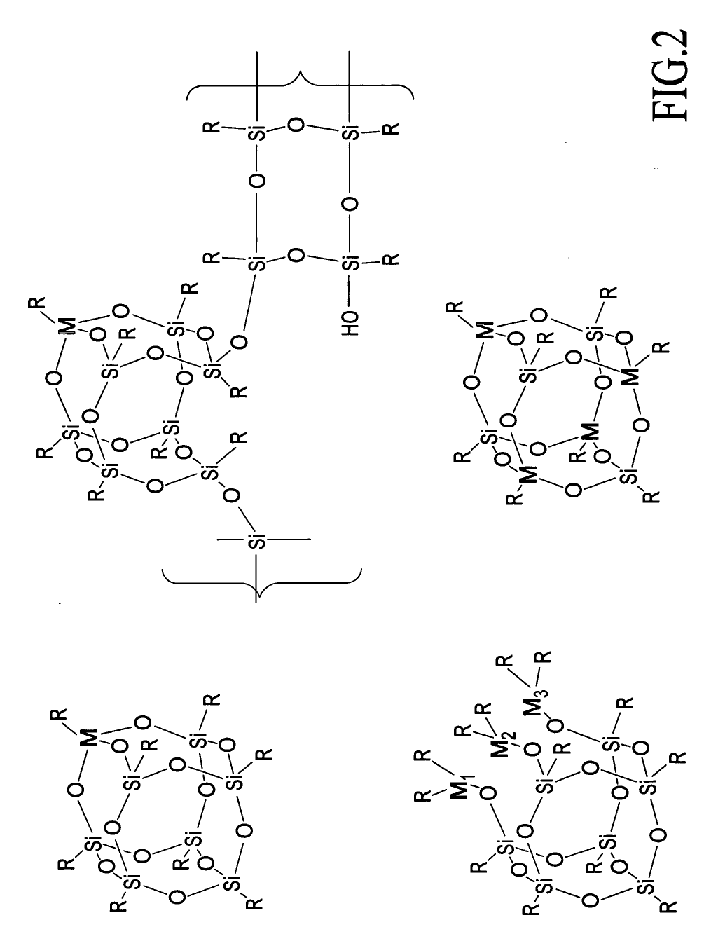

Silicon Containing Agents, such as the polyhedral oligomeric silsesquioxanes illustrated in FIGS. 1 and 2, are available as solids and oils and with or without metals. Both forms dissolve in molten polymers or in solvents, or can be reacted directly into polymers or can themselves be utilized as a binder material. For POSS, dispersion appears to be thermodynamically governed by the free energy of mixing equation (ΔG=ΔH-TΔS). The nature of the R group and ability of the reactive groups on the POSS cage to react or interact with polymers and surfaces greatly contributes to a favorable enthalpic (ΔH) term while the entropic term (ΔS) is highly favorable because of the monoscopic cage size and distribution of 1.0.

The above thermodynamic forces driving dispersion are also contributed to by kinetic mixing forces such as occur during high shear mixing, solvent blending or alloying. The kinetic dispersion is also aided by the ability of some Silicon Containing Agents to melt at or near the processing temperatures of most polymers.

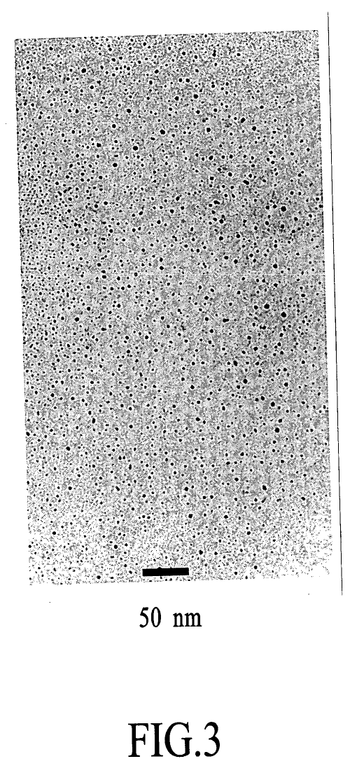

By controlling the chemical and processing parameters, nanoreinforcement and the alloying of polymers at the 1.5 nm level can be achieved for virtually any polymer system, as illustrated in FIG. 3. Silicon Containing Agents can also be utilized in combination with macroscopic fillers to render similar desirable benefits relative to enhancements of physical properties, barrier, stain resistance and radiation absorption. Thus, metallized or halogenated Silicon Containing Agents can be used in combination with tungsten or boron particles to provide highly neutron absorbing effective coatings with resistance toward other types of ionizing and non-ionizing radiation. In such instances, metallized Silicon Containing Agents containing isotopically enriched isotopes of boron, samarium, and gadolinium are of particular utility. Such coatings are of high value for terrestrial and space based electronics, mirrors, portals, structures, and vehicles, and for terrestrial and space based, sensors, microelectromechanical machines (MEMS), and food packaging.

The present invention shows that property enhancements can be realized by the direct blending of Silicon Containing Agents, and preferably nanostructured chemicals, into polymers.

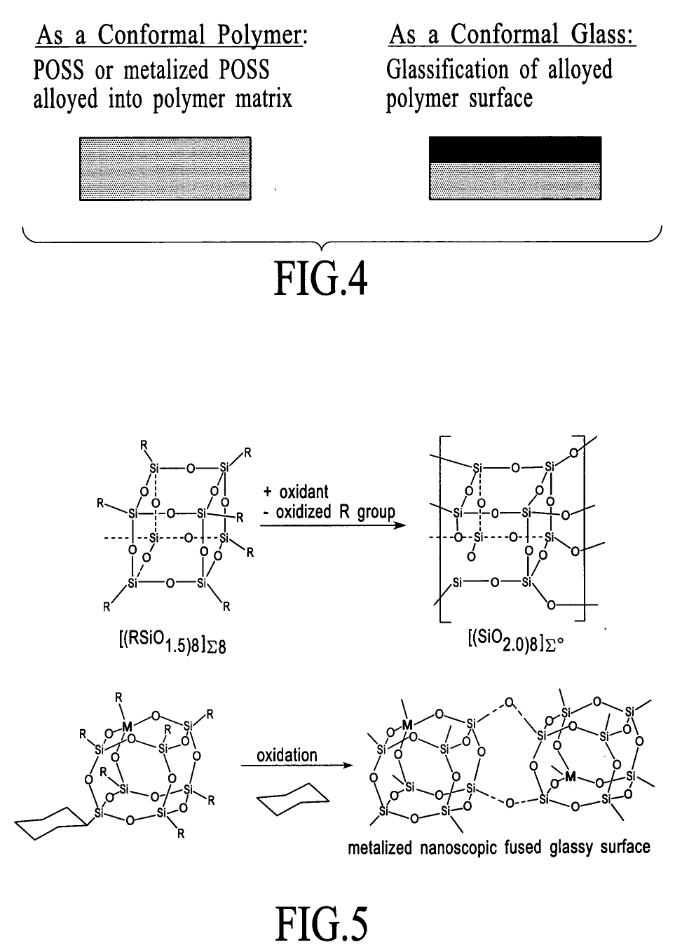

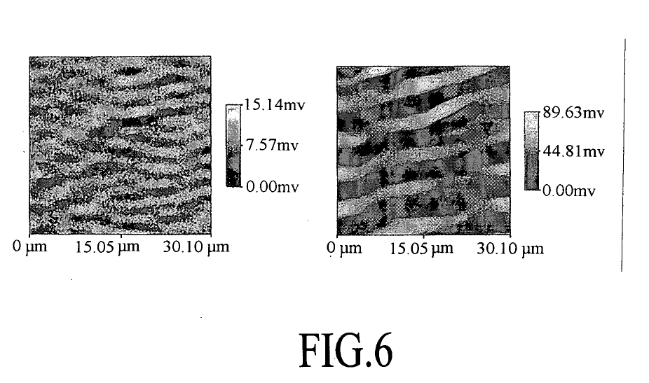

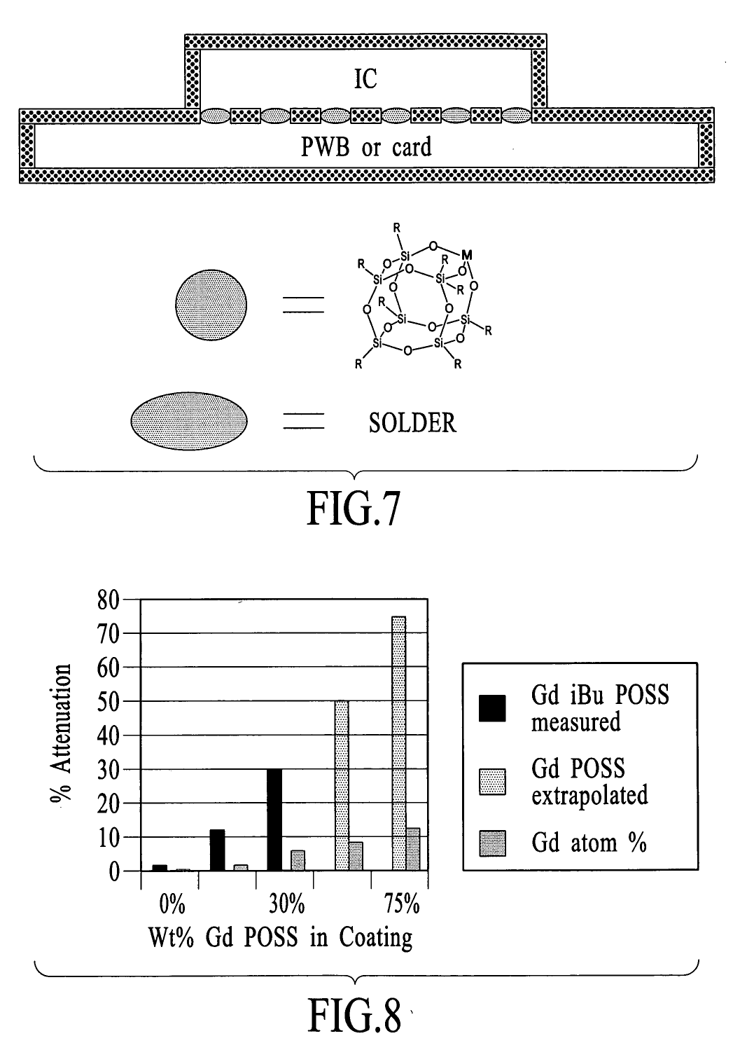

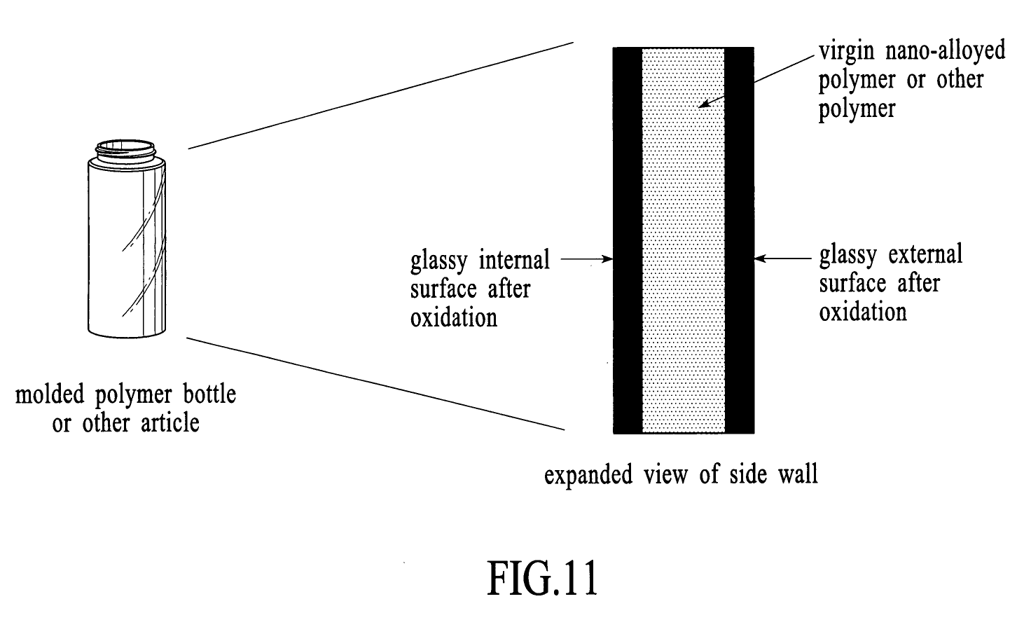

Because Silicon Containing Agents like nanostructured chemicals possess spherical shapes (per single crystal X-ray diffraction studies), like molecular spheres, and because they dissolve, they are also effective at reducing the viscosity of polymer systems. This benefits the processing, molding, or coating of articles using such nano-alloyed polymers, yet with the added benefits of reinforcement of the individual polymer chains due to the nanoscopic nature of the chemicals. Subsequent exposure of the nano-alloyed polymers to oxidizing agents results in the in situ formation of nanscopic glass on the exposed surfaces. FIGS. 4 and 6 illustrate the oxidation of silicones such as silsesquioxanes to glass. Upon exposure of the nano-alloyed polymer to an oxidizing source the silicon—R bonds are broken and the R group is lost as a volatile reaction byproduct. The valency to the silicon is maintained through the fusing of cages together by bridging oxygen atoms, thus rendering the equivalent of fused glass FIG. 5. Thus, ease of in situ formation of this glass surface layer is obtained through the use of nanostructured Silicon Containing Agents while the prior art requires the use a secondary coating or deposition method that results in formation of a micron thick layer of glass on the surface. The nanoscopically dispersed nature of the Silicon Containing Agents within and throughout the polymer affords the formation of the glass layer on the inside and outside of molded articles (FIG. 11). This is of tremendous advantage for articles such as bottles and pouches, as it allows for an in situ formed glass barrier inside and out, while the oxidizing source also provides sterilization. Such glass layers are also advantageous as they provide a more desirable surface for printing product information directly on the package.

Additional benefit from the use of such nano-alloyed polymers is the ability of such materials to self-heal in the event of a loss of the surface glass layer. In such an event, the nanoscopic Silicon Containing Agents present underneath the original glass surface are available to undergo in situ conversion to a new and healing glass surface layer upon exposure to an oxidant. Such control over compatibility, dispersability, size, and manufacturability is unprecedented for traditional fillers and coating technologies. Loading levels of the Silicon Containing Agents can range from 0.1% -99% by weight, with a preferred range from 1% -30% by weight.

### EXAMPLES

General Process Variables Applicable to All Processes

As is typical with chemical processes, there are a number of variables that can be used to control the purity, selectivity, rate and mechanism of any process. Variables influencing the process for the incorporation of Silicon Containing Agents into plastics include the size and polydispersity, and composition of the nanoscopic agent. Similarly the molecular weight, polydispersity and composition of the polymer system must also be matched between that of the Silicon Containing Agent and polymer. Finally, the kinetics, thermodynamics, processing aids, and fillers used during the compounding or mixing process are also tools of the trade that can impact the loading level and degree of enhancement resulting from incorporation. Blending processes such as melt blending, dry blending and solution mixing blending are all effective at mixing and alloying nanoscopic Silicon Containing Agents into plastics.

Alternate Method: Solvent Assisted Formulation. Silicon Containing Agents can be added to a vessel containing the desired polymer, prepolymer or monomers and dissolved in a sufficient amount of an organic solvent (e.g. hexane, toluene, dichloromethane, etc.) or fluorinated solvent to effect the formation of one homogeneous phase. The mixture is then stirred under high shear at sufficient temperature to ensure adequate mixing for 30 minutes and the volatile solvent is then removed and recovered under vacuum or using a similar type of process including distillation. Note that supercritical fluids such as CO₂ can also be utilized as a replacement for the flammable hydrocarbon solvents. The resulting formulation may then be used directly or for subsequent processing.

The examples provided below should not be construed as limiting toward specific material combinations or conditions.

### Example 1

### Moisture and Gas Barrier

A Silicon Containing Agent was incorporated into the polymer by melt compounding using a twin screw mixer and was processed into film followed by permeation measurements made on Mocon® equipment for nonglassified (FIG. 4a) and glassified (FIG. 4b) (oxidized) films.

Typical oxygen plasma treatments range from 1 seconds to 5 minutes under 100% power. Typical ozonolysis treatments range from 1 second to 5 minutes with ozone being administered through a CH₂Cl₂ solution with 0.03 equivalents O₃ per vinyl group. Typical steam treatments range from 1 second to 5 minutes. Typical oxidizing flame treatments range from 1 second to 5 minutes. Similar oxidation may be obtained through laser marking techniques via use of a laser operating in an oxidizing medium.

| | | % POSS | Oxidation | *P W/O | *P W | *Perm post |
|---|---|---|---|---|---|---|
| Polymer | POSS | Loading | Method | POSS | POSS | oxidation |
| PMMA | MA0702 | 5 | Plasma | 0.1 (O₂) | 0.07 (O₂) | 0.03 (O₂) |
| Nylon 6 | MS0825 | 1 | Plasma | | 180 (O₂) | 97 (O₂) |
| | | | | 130 (H₂O) | 1.56 (H₂O | |
| Nylon 6 | MS0830 | 1 | Plasma | 4-25 (O₂) | 0.14 (O₂) | |
| | | | | 130 (H₂O) | 1.52 (H₂O) | |

2- P (Permeability): cc cm m⁻² day⁻¹ atm⁻¹ (gm cm m⁻² day⁻¹ for H₂O)

The findings show that incorporation of small percentage loadings of POSS into the polymers resulted in reduced permeability to oxygen and water. The barrier to transport was further reduced by oxidation to form a surface glass.

### Example 2

### Neutron Radiation Barrier

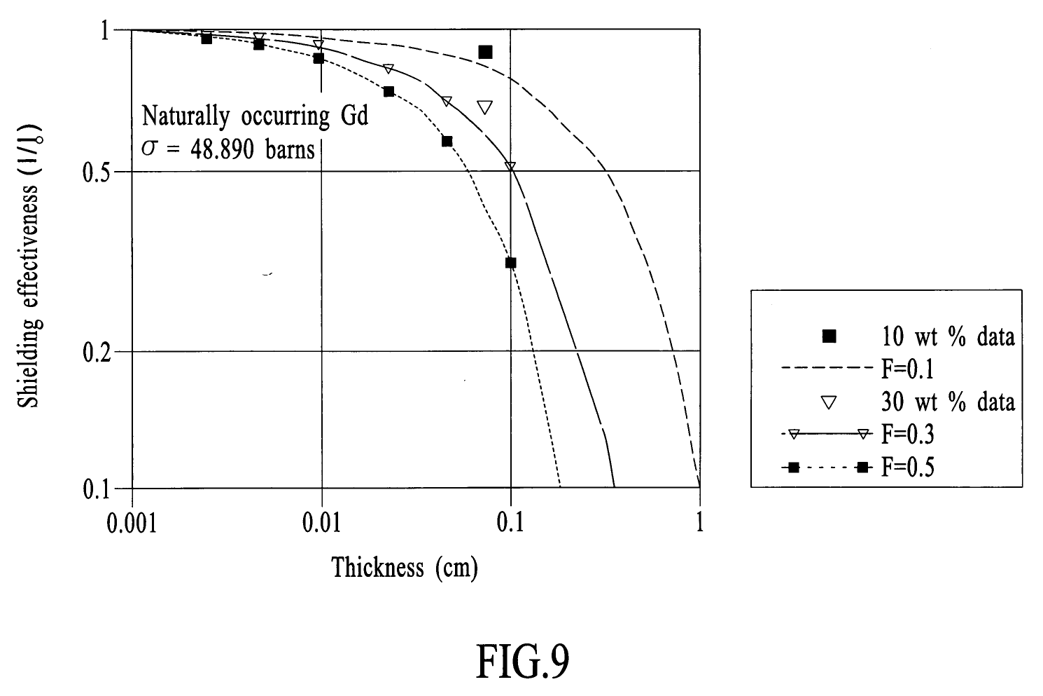

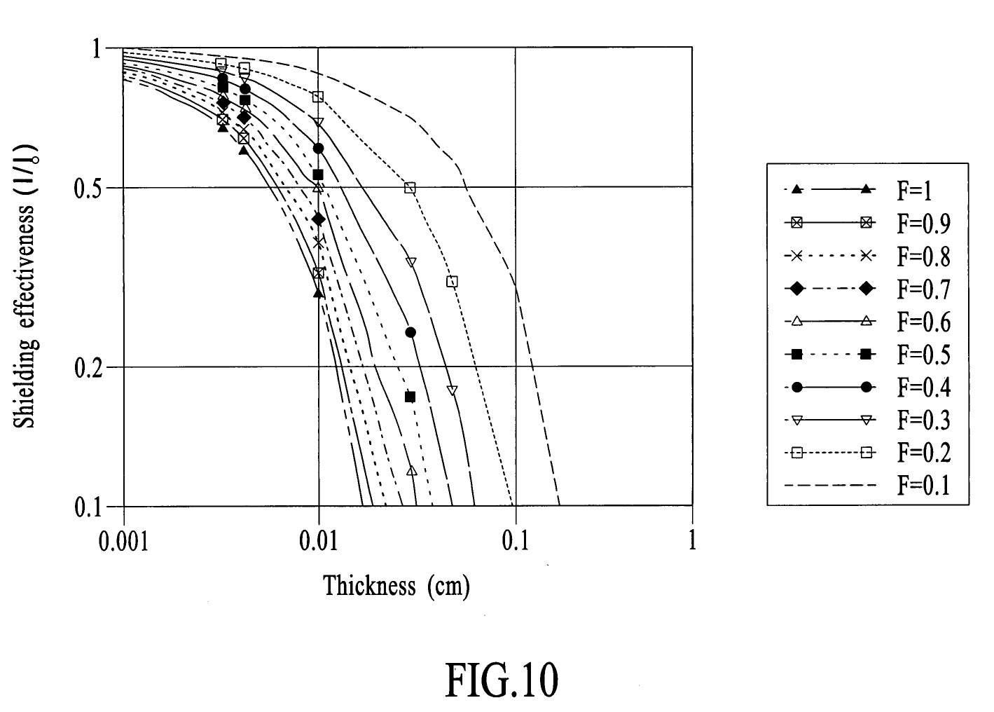

Optically clear samples containing various loading levels of Gd POSS were formulated into the FireQuench® 1287 resin system. A foil of Au was sandwiched between the Gd POSS® FireQuench® alloy. The samples were then exposed to a nuclear reactor that provides a watt fission neutron spectrum (energy range: 1-20 MeV, Ave.: ˜1 MeV). Only thermal (0.0253 ev) and epithermal (>0.5 eV) neutron flux were measured. The total neutron flux was measured using high purity gold foil. The reaction involved is Au-197(n,£^{Λ}) Au-198. A cadmium cover was used to determine the thermal component of the total neutron flux. The absolute flux was determined from the measured induced activity in the gold foils. Gamma spectroscopy is performed on an energy and efficiency calibrated high purity germanium detector (HPGe). The measured neutron flux distribution at 950 kW is 3.57E+07 n/cm2-sec thermal and 1.27E+07 n/cm2-sec epithermal. The calculated error in flux measurement is 0.75%. The reduction in neutron flux scaled linearly with the wt % of Gd POSS loaded into the resin (FIG. 8). It was calculated that for a ⅔ reduction in thermal neutrons a 1 mm thick conformal coating containing 50% by weight natural abundance Gd POSS would be required (FIG. 9) while only a 0.1 mm thick coating of isotopically enriched 157 Gd would provide the sample level of protection (FIG. 10). Similar results were obtained for boron and samarium POSS systems. Thus, protection of electronic components from thermal neutron damage can be achieved using conformal coatings containing B, Sm, or Gd POSS additives. These additives can also be incorporated into composite resins to render structural composites which also aid as neutron shields. The large number of hydrogen atoms per POSS cage further aids in thermalizing fast neutrons, thus enabling their capture by the B, Sm or Gd atoms. The use of B, Sm and Gd POSS systems to thermalize fast neutrons and capture them also enables them to serve as more effective neutron capture agents in fast neutron tumor therapy.

### Example 3

### UV, VUV, Visible Radiation Barriers and Emissive Additives

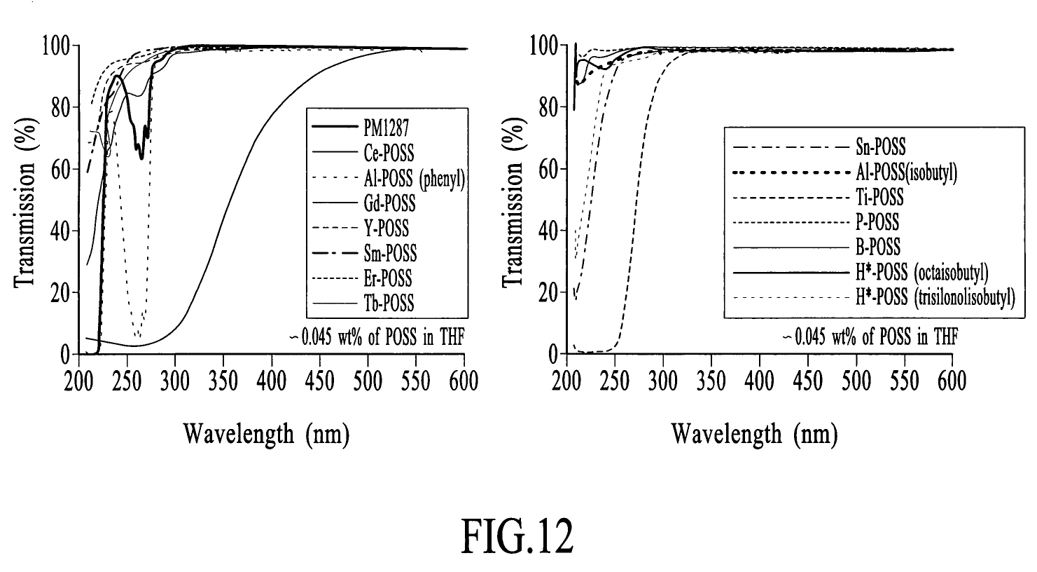

Samples of various metallized POSS were exposed to UV through visible radiation and their absorption characteristics are shown in FIG. 12. It is clear that the absorption characteristics can be tuned through adjustment of the metal contained in the system. For example, Ce and Ti based POSS are particularly good absorbers for a broader spectrum of UV radiation than a narrowly absorbing Al POSS. Further, it has been shown these systems can be incorporated into optically clear polymers and composites and subsequently converted into nanoscopically thin glass surface layers which may offer an additional advantage as radiation absorbing top coats. These coatings will find utility in a variety of polymers including silicones which are degraded at 150 nm and in polycarbonate which is degraded at 243 nm.

Additionally useful are the emissive characteristics of several metallized POSS systems. For example, Tb POSS is a strong green emitter upon exposure to black light while Er POSS is an emitter upon excitation by X-ray. Such systems alloyed into polymers or incorporated into nanoscopically controlled glasses have utility in optical displays, signs, and as protective coatings on solar cells in which they could absorb damaging or unuseful radiation and reemit it in a range useful for electricity generation by the solar cell.

### Example 4

### Refractive Index layer

Optically clear samples containing various metalized POSS were formulated into the FireQuench® 1287 resin system. The refractive index values were measured using a refractometer at different incident wavelengths. The series shows an ability to fine tune the refractive index both narrowly through changes in the metal or radically through changes in the functionality (e.g. thiol). The more polarizable electrons on the metal or the R group on the POSS cage leads to a larger the shift in refractive index.

| Sample | RI@589 nm | RI@414 nm |
|---|---|---|
| PM1287 | 1.4553 | 1.48660 |
| Er-POSS | 1.4582 | 1.48590 |
| Tb-POSS | 1.4586 | 1.48680 |
| Gd-POSS | 1.4585 | 1.49460 |
| Sm-POSS | 1.4591 | 1.48750 |
| P-POSS | 1.4548 | 1.49060 |
| Y-POSS | 1.4580 | 1.48660 |
| Sn-POSS | 1.4607 | |
| Octathiol | | |
| POSS | 1.5470 | |

### Example 5

### Condensation Polymerization Catalyst

Optically clear samples of two part polyurethane, epoxide, and siloxane were obtained through catalysis with various metalized POSS. For example, Ti POSS loaded in the 1 ppm level and higher was found to promote the rapid condensation polymerization of polyurethane while Sn POSS was found to be advantageous in the cure of silanol and silane formulated silicones. In each case, cure was accelerated through increase of temperature and catalyst loading. A particular advantage of these metallized catalysts are their low flammability and migrations due to their large atomic mass. A further advantage is their ability to be converted into glasses and to serve as fillers to reduce shrinkage and improve the oxidation of permeation properties of the resulting polymer.

1. A method for formation of a glass layer on a polymer surface comprising the steps of:
(a) incorporating at least one nanoscopically dispersed and sized Silicon Containing Agent into a polymer; and
(b) oxidizing the surface to form a glass layer.

2. The method of claim 1, wherein the glass layer provides a barrier to attenuate a member of the group consisting of water, oxygen, neutrons, ultraviolet radiation, and visible raditation.

3. The method of claim 1, wherein the refractive index of the polymer is controlled through selection of the Silicon Containing Agent.

4. The method of claim 1, wherein the emissive properties of the polymer are controlled through selection of the Silicon Containing Agent.

5. The method of claim 1, further comprising laser marking the polymer after formation of the glass layer.

6. The method of claim 1, wherein a plurality of Silicon Containing Agents is incorporated into the polymer.

7. The method of claim 1, wherein the polymer is in a physical state selected from the group consisting of oils, amorphous, semicrystalline, crystalline, elastomeric, and rubber.

8. The method of claim 1, wherein the polymer is a polymer coil, a polymer domain, a polymer chain, a polymer segment, or a mixture thereof.

9. The method of claim 1, wherein the Silicon Containing Agent reinforces the polymer at a molecular level.

10. The method of claim 1, wherein the incorporation is nonreactive.

11. The method of claim 1, wherein the incorporation is reactive.

12. The method of claim 1, wherein a physical property of the polymer is improved.

13. The method of claim 12, wherein the physical property is selected from the group consisting of adhesion, water repellency, fire retardancy, density, low dielectric constant, thermal conductivity, glass transition, viscosity, melt transition, storage modulus, relaxation, stress transfer, abrasion resistance, fire resistance, biological compatibility, gas permeability, porosity, radiation absorption, radiation emission, refractive index, and optical quality.

14. The method of claim 1, wherein the incorporation is accomplished in combination with at least one other filler or additive that is macroscopic or nanoscopic.

15. A method of condensation polymerization catalysis of monomers comprising the method of claim 1 wherein the Silicon Containing Agent is metallized, and further comprising the step of polymerizing the monomers before the surface oxidation step.

16. A method for formation of a neutron radiation barrier comprising the step of incorporating a metal selected from the group consisting of B, Gd, and Sm into a POSS cage.

17. The method of claim 17, wherein the barrier is used as a therapeutic chemical in fast neutron therapy.
